(19) United States
(12) Patent Application Publication
(10) Pub. No.: US 2012/0037224 A1
(43) Pub. Date: Feb. 16, 2012

(54) SOLAR BATTERY CELL AND METHOD OF MANUFACTURING THE SAME

(75) Inventors: Masahiro Fujikawa, Tokyo (JP); Shigeru Matsuno, Tokyo (JP)

(73) Assignee: Mitsubishi Electric Corporation, Tokyo (JP)

(21) Appl. No.: 13/266,513

(22) PCT Filed: Mar. 2, 2010
(86) PCT No.: PCT/JP2010/001394

§ 371 Date: Oct. 27, 2011

(30) Foreign Application Priority Data
Apr. 29, 2009 (JP) 2009-110206

(51) Int. Cl. H01L 31/0224; H01L 31/18

(52) U.S. Cl. 136/256; 438/98; 257/E31.124

(57) ABSTRACT

A solar battery cell including: a semiconductor substrate; front-surface asperities formed on the principal surface on a light-receiving side of the semiconductor substrate; a semiconductor layer having a conductive type and formed along the front-surface asperities; and an anti-reflection film formed on the light-receiving side of the semiconductor layer, a passivation film is formed on the principal surface on the back-surface side of the semiconductor substrate, and at least one opening is provided in the passivation film. A first back-surface electrode is formed on the passivation film so as to overlap the entire area occupied by the opening and to cover the opening, and a second back-surface electrode is formed on the passivation film so as to overlap the entire area occupied by the first back-surface electrode and to cover the first back-surface electrode.

### FIELD

The present invention relates to a solar battery cell and to a method of manufacturing the same.

### BACKGROUND

In most conventional crystalline silicon solar batteries having a PN junction, an n-type diffusion layer is formed over the entire front principal surface (hereinafter referred to as a front surface), which is the principal surface on the light-receiving side of a p-type polycrystalline silicon substrate, and fine asperities and a front-surface electrode are provided on the front surface on the light-receiving side. In such a solar battery cell, its back principal surface (hereinafter referred to as a back surface), which is the principal surface on the side opposite to the light-receiving side, is subjected to processing to provide a BSF (Back Surface Field, hereinafter referred simply to as BSF) and BSR (Back Surface Reflection, hereinafter referred simply to as BSR) so that the conversion efficiency of the solar battery cell is improved by the reflection of photo-generated carriers by the BSF and the reflection of incident light by the BSR.

In such a solar battery cell, as the thickness of a base layer decreases, the function of the BSR is not fully exerted. Therefore, there is a solar battery cell having a structure in which the BSF and the BSR are separately provided while an electrode is easily formed (see, for example, Patent Literature 1).

When a BSF layer is formed by printing an Al paste material over the entire surface of a thin large-area substrate and then firing the printed Al paste material, the substrate can be warped or cracked. For example, to prevent the warpage or cracks, a method is used in which the Al paste material is printed in a dot pattern and then fired, or a method is used in which the BSF layer is formed over the entire surface using BBr₃ by thermal diffusion. However, sufficient conversion efficiency cannot by obtained by any of these methods. In one solution, a flat back-surface electric field layer is formed over the entire back surface of the substrate, and a dot-patterned back-surface electric field layer extending deeper than the flat back-surface electrode is formed at predetermined positions on the back surface of the substrate (see, for example, Patent Literature 2).

### Citation List

### Patent Literature

Patent Literature 1: Japanese Patent Application Laid-open No. H1-179373

Patent Literature 2: Japanese Patent Application Laid-open No. H4-044277

### SUMMARY

### Technical Problem

However, with the invention described in Patent Literature 1, the reflection of light from the back surface is small, and the light is absorbed by the back-surface electrode. Therefore, the utilization rate of the light passing through the substrate is small.

In the invention described in Patent Literature 2, a passivation film used as a surface protection film for back-surface electrodes is formed to have dot-shaped openings. After electrodes are formed by firing, a back-surface reflecting film is optionally formed. A plurality of such solar battery cells with or without the back-surface reflecting film may be arranged and sandwiched between films or tempered glass plates to form an integrated solar battery module. In this configuration, the utilization rate of long-wavelength light can be improved by the reflection from a back sheet disposed on the back side of the solar battery cells in the solar battery module and serving as a weather-resistant film for protecting the solar battery module from ultraviolet rays, water vapor, salt, and the like.

However, when such a configuration is used, since a paste prepared by mixing aluminum powder with a particle diameter of several μm, a resin, and an organic solvent is used to form the dots by printing, the aluminum particles are aggregated after the paste is dried, and this results in low structural strength. Therefore, the dot-shaped back-surface electrodes may be peeled off during a front-surface electrode printing step performed before a firing step or during conveyance. In such a case, an aluminum alloy layer and a P⁺ layer for a BSF are not formed adequately. This results in an undesirable increase in contact resistance, and the characteristics of the solar battery cell deteriorate.

In the electrodes containing aluminum particles, the adhesion properties of the particles are low even after the electrode firing step at 700 to 800° C. As the resistance component due to surface oxidation and the like increases, the series resistance component of the back-surface electrodes as a whole increases, and this undesirably results in deterioration of the characteristics of the solar battery cell.

The present invention has been made to solve the foregoing problems, and it is an object of the invention to obtain a robust solar battery cell having good characteristics by obtaining a back-surface electrode that provides sufficient back-surface protection and back-surface reflection effects and has high structural strength and a small resistance component.

### Solution To Problem

In order to solve the aforementioned problems and attain the aforementioned object, a solar battery cell according to one aspect of the present invention is constructed in such manner as to have a semiconductor substrate; front-surface asperities formed on a principal surface on a light-receiving surface side of the semiconductor substrate; a semiconductor layer having a conductive type and formed along the front-surface asperities; and an anti-reflection film formed on the light-receiving side of the semiconductor layer, wherein a passivation film is formed on a principal surface on a back-surface side of the semiconductor substrate, at least one opening is provided in the passivation film, a first back-surface electrode is provided on the passivation film so as to overlap an entire area occupied by the opening and to cover the opening, and a second back-surface electrode is provided on the passivation film so as to overlap an entire area occupied by the first back-surface electrode and to cover the first back-surface electrode.

### Advantageous Effects of Invention

In the present invention, an aluminum back-surface electrode and another back-surface electrode stacked thereon and containing aluminum and silicon are provided. This provides improved structural strength and prevents peeling of the electrodes during manufacturing, and the back-surface electrodes obtained have high conductivity. Accordingly, a robust solar battery cell having a good back-surface protection effect, a good back-surface reflection effect, and high conversion efficiency can be obtained.

### BRIEF DESCRIPTION OF DRAWINGS

FIG. 1 is a transparent view of a part of a solar battery cell in a first embodiment of the present invention as viewed from a back surface side.

FIG. 2 is a cross-sectional view cut along A-B in FIG. 1.

FIG. 3 is a diagram illustrating one mode in a step during manufacturing of the solar battery cell in the first embodiment of the present invention.

FIG. 4 is a diagram illustrating one mode in a step during manufacturing of the solar battery cell in the first embodiment of the present invention.

FIG. 5 is a diagram illustrating one mode in a step during manufacturing of the solar battery cell in the first embodiment of the present invention.

FIG. 6 is a diagram illustrating one mode in a step during manufacturing of the solar battery cell in the first embodiment of the present invention.

FIG. 7 is a diagram illustrating one mode in a step during manufacturing of the solar battery cell in the first embodiment of the present invention.

FIG. 8 is a diagram illustrating one mode in a step during manufacturing of the solar battery cell in the first embodiment of the present invention.

FIG. 9 is a diagram illustrating one mode in a step during manufacturing of the solar battery cell in the first embodiment of the present invention.

FIG. 10 is a diagram illustrating one mode in a step during manufacturing of the solar battery cell in the first embodiment of the present invention.

FIG. 11 is a diagram illustrating one mode in a step during manufacturing of the solar battery cell in the first embodiment of the present invention.

FIG. 12 is a diagram illustrating one mode in a step during manufacturing of the solar battery cell in the first embodiment of the present invention.

FIG. 13 is a flowchart showing the process of manufacturing the solar battery cell in the first embodiment of the present invention.

FIG. 14 is a transparent view of a part of a solar battery cell in a second embodiment of the present invention as viewed from a back surface side.

### DESCRIPTION OF EMBODIMENTS

### First Embodiment

An embodiment of the present invention will next be described with reference to the drawings. In the following description of the drawings, identical or similar parts are denoted by identical or similar reference numerals. However, the drawings are only illustrative, and it should be noted that the dimensional proportions and the like are different from the actual ones. Therefore, the specific dimensions and the like should be determined in consideration of the following description. It is needless to say that dimensional relationships and proportions may be partially different between the drawings.

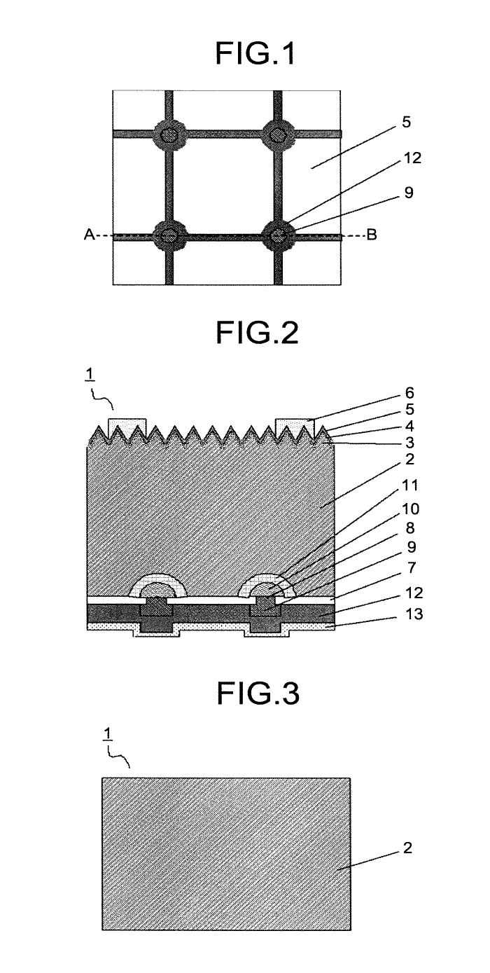

FIG. 1 is a transparent view of a part of a solar battery cell in a first embodiment of the present invention as viewed from a back surface side (down-side electrodes on the back surface side are shown). FIG. 2 is a cross-sectional view cut along A-B in FIG. 1.

In these figures, the solar battery cell 1 includes a p-type single-crystalline or poly-crystalline silicon substrate 2, which is a semiconductor substrate, and front-surface asperities 3 with a depth of about 10 μm for trapping light which are formed on the principal surface on the light-receiving side of the silicon substrate 2. An n-type diffusion layer 4, which is a poly-crystalline semiconductor layer of one conductive type, is formed to a thickness of about 0.2 μm in the front-surface asperities 3 along the light-receiving side to form a PN junction. An anti-reflection film 5 for reducing reflection to improve the utilization rate of light is formed on the light-receiving side of the n-type diffusion layer 4, and these form a photoelectric conversion unit. A front-surface electrode 6 composed of a plurality of grid electrodes and a plurality of bus electrodes orthogonal thereto is formed on the upper surface of the anti-reflection film 5. The silicon substrate 2 is not limited to a p-type single-crystal or poly-crystal and may be an n-type single-crystal or poly-crystal.

A passivation film 7 for terminating defects in silicon with hydrogen to suppress recombination of minority carriers, is formed on the principal surface on the back surface side of the silicon substrate 2. The passivation film 7 has openings 8 formed therein. Dot-shaped aluminum electrodes 9 used as first back-surface electrodes are formed so as to cover the openings 8 from the back surface side, and a sintered aluminum-silicon alloy layer 10 is formed in the silicon substrate 2 at positions on the light-receiving side of the aluminum electrodes 9. A BSF layer 11 being a P⁺ layer is formed by diffusion of aluminum so as to cover the light-receiving side of the alloy layer 10.

An Al—Si electrode 12 used as a second back-surface electrode is formed on the back surface side of the passivation film 7 so as to cover the aluminum electrodes 9 and to line-connect the aluminum electrodes 9 to each other. A BSR being a back-surface reflecting film 13 is formed so as to cover the passivation film 7, the aluminum electrodes 9, and the Al—Si electrode 12 and to cover the entire principal surface on the back-surface side of the silicon substrate 2.

Next, a method of manufacturing the solar battery cell in the first embodiment of the present invention will be described with reference to FIGS. 3 to 12 and FIG. 13.

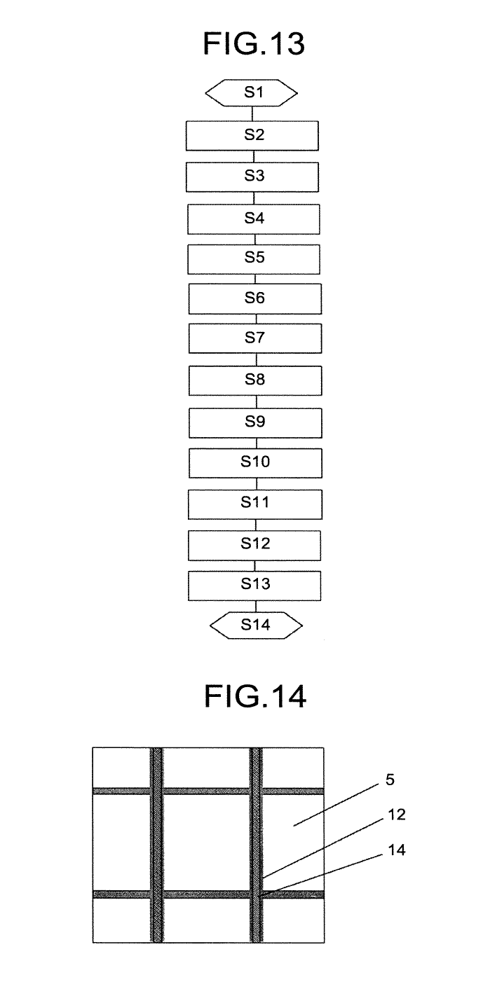

FIGS. 3 to 12 are diagrams illustrating modes in the steps of manufacturing the solar battery cell of the present invention. FIG. 13 is a flowchart showing the process of manufacturing the solar battery cell. In FIG. 13, S1 is the start; S2 is a substrate washing step; S3 is a front-surface etching step; S4 is an n-type diffusion layer forming step; S5 is an anti-reflection film forming step; S6 is a back-surface etching step; S7 is a passivation film forming step; S8 is an opening forming step; S9 is a first back-surface electrode forming step; S10 is a second back-surface electrode forming step; S11 is a front-surface electrode forming step; S12 is a heat treatment and firing step; S13 is a back-surface reflecting film forming step; and S14 is the end. Next, the steps in FIGS. 3 to 12 will be described on the basis of the flow shown in FIG. 13.

In FIG. 3, a p-type poly-crystalline silicon substrate is used as the silicon substrate 2, and the silicon substrate 2 is washed with hydrogen fluoride and pure water.

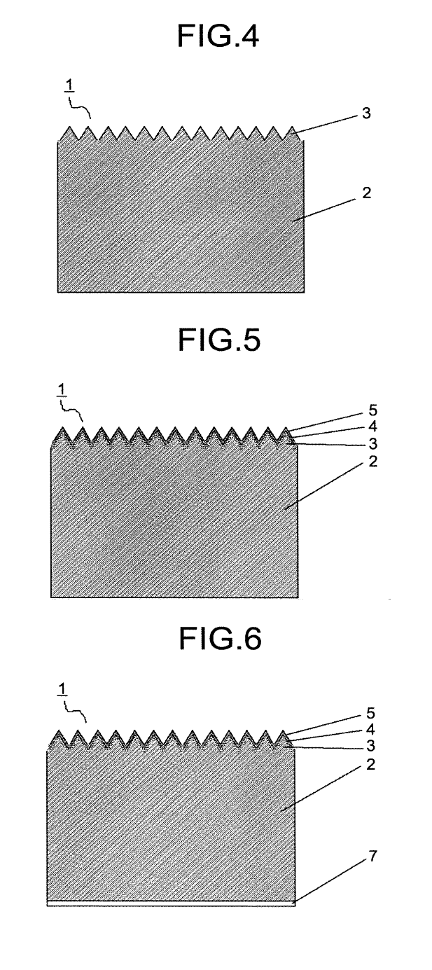

In FIG. 4, the silicon substrate 2 is immersed in, for example, a solution mixture of an NaOH alkaline solution and isopropyl alcohol and is wet-etched to form surface asperities of about 10 μm, and front-surface asperities 3 are thereby formed. Asperities of about 1 to 3 μm may be formed on the front surface by a dry etching process such as RIE (reactive ion etching). Alternatively, fine hemispherical asperities may be formed by forming an etching mask on the front surface by plasma CVD, forming a plurality of openings in the etching mask, and then etching the front surface with hydrogen fluoride-nitric acid. With the latter asperity formation method, asperities arranged regularly can be formed irrespective of the orientation of the silicon substrate 2, and the light trapping efficiency is improved.

In FIG. 5, the silicon substrate 2 having the front-surface asperities 3 formed on the front surface is subjected to thermal diffusion in phosphorus oxychloride (POCl₃) gas at high temperatures by a vapor phase diffusion method to form an n-type diffusion layer 4. The concentration of phosphorus to be diffused can be controlled by changing the concentration of the POCl₃ gas, the temperature of the atmosphere, the heating time, and the like. The sheet resistance of the substrate after diffusion is 40 to 80Ω/cm². After the diffusion step, an anti-reflection film 5 is formed. In this embodiment, a gas mixture of silane and ammonia was used to form an 80 nm thick silicon nitride film by plasma CVD.

Next, the steps of forming back-surface electrodes by printing are performed. In FIG. 6, since an n-type diffusion layer has been formed also on the back surface in the diffusion step, this n-type diffusion layer is first removed by alkaline etching, and then a passivation film 7 is formed. The passivation film 7 is, for example, a silicon oxide film or a silicon nitride film. In this embodiment, a silicon nitride film similar to the anti-reflection film 5 was formed to a thickness of 200 nm by plasma CVD.

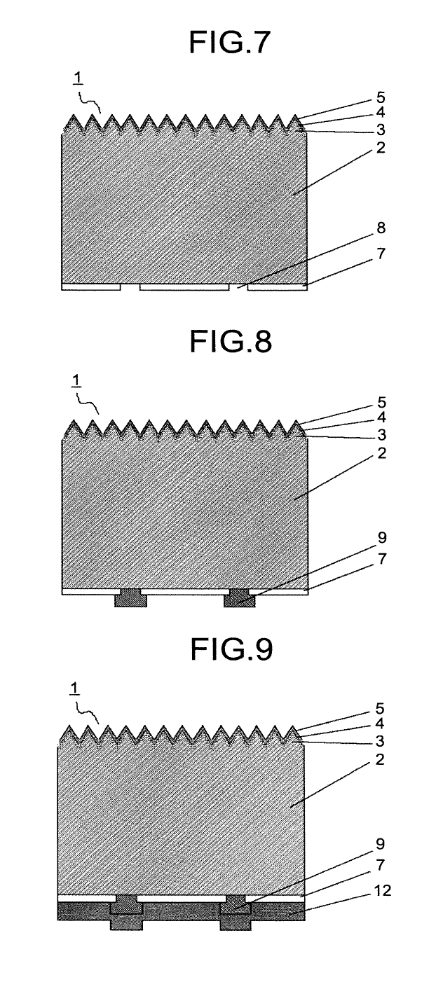

In FIG. 7, a plurality of openings 10 are formed in the deposited passivation film 7. Examples of the method of forming the openings 8 include a photomechanical method including resist application, exposure to light, and etching; and a mechanical opening formation method. In this embodiment, the openings are formed using a YAG laser (wavelength: 532 nm) so that the process can be completed in a short time. The silicon substrate 2 is sucked and secured to an operation stage. Then the stage is moved in an X direction, and the laser is moved in a Y direction to form a pattern including 0.2 mm diameter openings with a pitch of 0.7 mm by irradiation with the laser beam.

The pitch and diameter of the openings in the laser pattern are changed depending on the relationship between the area of the electrodes and the area of the passivation film 7. When the diameter of the openings is large, a sufficient BSF layer 11 can be formed, so that the resistance between the aluminum electrodes 9 and the silicon substrate 2 can be reduced. In contrast, when the diameter of the openings is small, the depth of the BSF layer 11 formed is small, so that the resistance between the aluminum electrodes 9 and the silicon substrate 2 becomes large. As the diameter of the openings increases, the area of the passivation film 7 decreases, so that the passivation effect decreases. In contrast, as the diameter of the openings decreases, the area of the passivation film 7 increases. In this case, a sufficient passivation effect can be obtained, and the values of the open-circuit voltage Voc and the short-circuit current Isc can be increased.

In FIG. 8, dot-shaped aluminum electrodes 9 used as the first back-surface electrodes are formed at the positions conforming to the openings 8 by printing. The aluminum electrodes 9 are formed by printing a paste containing aluminum using a printing device through a printing mask designed to have openings at the same positions as those in the laser opening pattern. In this embodiment, the aluminum electrodes 9 are formed to have a diameter of about 0.3 to 0.4 mm that is larger than the diameter of the laser openings, in consideration of the accuracy of printing positions and the accuracy of the mask. When stainless steel with 250 mesh is used as the printing mask, the thickness of the electrodes is about 20 μm.

The printed aluminum electrodes are dried at approximately 200° C.

In FIG. 9, an Al—Si paste containing aluminum particles and silicon particles is printed over the above-formed dot-shaped aluminum electrodes 9 to form an Al—Si electrode 12 being the second back-surface electrode. The aluminum electrodes 9 have been printed on the passivation film 7 in an overlapping manner and are therefore larger than the printing pattern by about 0.03 to 0.05 mm.

Therefore, the Al—Si electrode 12 is designed to have portions having a diameter of about 0.35 to 0.45 mm, which is larger than that formed using the printing mask for the aluminum electrodes 9, so as to cover the down-side layer. When a printing mask with 250 mesh similar to that for the aluminum electrodes 9 is used as the printing mask for the Al—Si electrode 12, the thickness of the electrode is about 10 to 20 μm. When the width of the Al—Si electrode 12 that covers the aluminum electrodes 9 and line-connects the aluminum electrodes 9 to each other is large, the conduction resistance is low, but the reflection efficiency by the back-surface reflecting film 13 is lowered. Therefore the width was about 0.3 to 0.4 mm.

As for the ratio between the aluminum particles and the silicon particles contained in the Al—Si paste used, as the ratio of the silicon particles mixed increases, the adhesion between the paste and the aluminum electrodes 9 increases, but the conduction resistance tends to increase. The composition ratio of silicon based on 100 parts by weight of aluminum is 5 to 20 parts by weight. This mixing ratio is a desirable value to ensure electrode strength enough to prevent peeling and to provide a sufficient conduction resistance value. When the composition ratio of silicon is 5 parts by weight or less, the electrode strength tends to be low. When the composition ratio of silicon is 20 parts by weight or more, the conduction resistance tends to be high. The printed Al—Si electrode 12 is dried at approximately 200° C.

The steps of forming the back-surface electrodes by printing have now been completed, and a front-surface electrode is next formed. The front-surface electrode is formed by printing a pattern including a plurality of thick bus electrodes and a plurality of narrow grid electrodes orthogonal to the bus electrodes. A paste composed of a resin containing silver particles, an organic solvent, and the like is used for printing. The electrode formed by printing is dried at approximately 200° C.

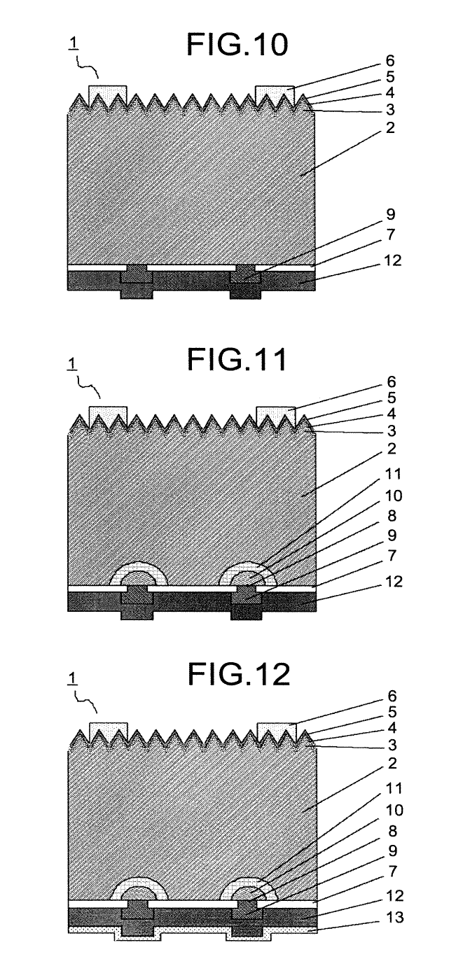

Next, the front-surface and back-surface electrodes are fired. The firing is performed at 800° C. using an infrared heating furnace. In FIG. 10, the previously formed front-surface electrode 6 comes into contact with silicon by a fire-through process in the firing step. Then, as shown in FIG. 11, aluminum in the aluminum electrodes 9 is melted together with silicon to form an alloy layer 10. In addition, a BSF layer 11, which is a P⁺ layer formed by diffusion of Al, is formed so as to cover the alloy layer 10. The thickness of the electrodes is about 20 to 25 μm, and the alloy layer 10 is formed to about 10 to 20 μm. A sufficient BSF layer 11 of about 4 to 8 μm is thereby obtained.

After firing, heating at 400° C. in a hydrogen atmosphere is performed, and then a back-surface reflecting film 13 is formed as shown in FIG. 12. The back-surface reflecting film 13 is deposited by sputtering to be made of Ag with a thickness of about 500 to 1,000 nm.

### Second Embodiment

FIG. 14 is a transparent view of a part of a solar battery cell in a second embodiment of the present invention as viewed from the back surface side (down-side electrodes on the back surface side are shown). In the description of the first embodiment above, the aluminum electrodes 9 have a dot shape. However, in the solar battery cell having the back-surface passivation structure according to the invention, sufficient characteristics may not be obtained when polycrystalline silicon is used and the area of the openings is small. This is because the reaction of silicon is changed by the crystal grain boundaries to cause the contact state to be unstable.

Therefore, in the solar battery cell 1 in the second embodiment of the present invention, the openings in the passivation film 7 are formed to have a stripe shape, and the aluminum electrodes 9 being the first back-surface electrodes are formed as stripe electrodes 14 having a stripe shape so as to pass through the grain boundaries of the poly-crystal, so that the contact area is increased.

The dot shape shown in the first embodiment above may be used with the area occupied by the dots being increased. However, to allow the aluminum electrodes 9 to pass through the grain boundaries of the poly-crystal, the diameter of the dots must be considerably large, and this is inefficient.

The stripe-shaped openings and the stripe-shaped electrodes 14 shown in the second embodiment of the invention can be very easily formed by changing both the processing pattern for the YAG laser and the pattern shape of the printing mask shown in the first embodiment above. In the above description of the second embodiment of the invention, the back-surface electrodes are formed to have a stripe shape. However, the back-surface electrodes may have a cross shape in which vertical and horizontal lines cross each other or a circular or quadrilateral shape that is, however, slightly poor in efficiency.

Next, a specific example of the method of manufacturing the solar battery cell 1 shown in the second embodiment and the performance of the solar battery cell 1 obtained are shown.

In the invention according to the second embodiment, a p-type polycrystalline silicon substrate of 150×150 mm square and having a thickness of 0.18 mm was used as the silicon substrate 2. Since the process until the passivation film 7 or a silicon nitride film similar to the anti-reflection film 5 is deposited to a thickness of 200 nm by plasma CDV is the same as that in the first embodiment above, the description thereof is omitted. In this embodiment, in the step of forming the n-type diffusion layer 4, n-type diffusion was performed on the front surface so that the sheet resistance was 50 to 60Ω/cm².

Next, a YAG laser beam was applied to the deposited passivation film 7 to remove 60 μm-wide stripe portions of the passivation film 7 with a pitch of 1.5 mm, and a plurality of stripe-shaped openings were thereby formed.

To form back-surface electrodes, first, an aluminum paste was used to form stripe-shaped electrodes 14 having a width of 60 μm by printing so as to cover the plurality of stripe-shaped openings. The paste was dried at about 200° C. Then an aluminum-silicon mixed paste having a composition ratio of silicon of 12 parts by weight based on 100 parts by weight of aluminum was used to form a 100 μm-wide Al—Si electrode 12 having a lattice shape with a pitch of 1.5 mm by printing so as to overlap the stripe-shaped electrodes 14.

Next, a paste containing silver was used to form a front-surface electrode 6 by printing into a pattern in which a plurality of thick bus electrodes having an electrode width of 2.0 mm crossed a plurality of narrow grid electrodes having an electrode width of 0.1 mm. Then the paste was dried at 200° C., and firing was performed at 800° C. using an infrared heating furnace. Finally, a back-surface reflecting film 13 was formed. The back-surface reflecting film 13 was deposited using Ag to a thickness of about 800 nm by sputtering. In the thus-formed solar battery cell 1, peeling of the back-surface electrodes was not observed.

The cell characteristics of the solar battery cell according to the second embodiment obtained by the above method were measured using a sunlight simulator. A conventional solar battery cell in which a paste containing aluminum was applied to the entire back surface and then fired without the passivation film 7 was used for comparison. The results showed that, in the conventional solar battery cell including the aluminum electrode formed over the entire surface, the open-circuit voltage Voc was 620 mV, the short-circuit current density Jsc was 32.5 A/cm², and the conversion efficiency E_{ff} was 16.5%. However, in the solar battery cell according to the second embodiment, Voc was 625 mV, Jsc was 34.5 A/cm², and the conversion efficiency E_{ff} was 17.0%. Therefore, the photo-electron conversion efficiency was found to be improved.

### Third Embodiment

In the first embodiment above, the Al—Si paste containing aluminum particles and silicon particles is printed over the formed aluminum electrodes to form the Al—Si electrode used as the second back-surface electrode. However, an Al—Si alloy prepared by melting aluminum and silicon may be used. In this case, a paste composed of powder of the granulated alloy or a paste containing the powder is used.

The composition ratio of silicon to aluminum in the Al—Si alloy is 5 to 20 parts by weight of silicon based on 100 parts by weight of aluminum, as in the mixing ratio when the aluminum particles and silicon particles are used.

When the powder composed of the Al—Si alloy is used, the warpage of the substrate can be reduced as compared to the case in which a paste composed of a powder mixture of aluminum particles and silicon particles is used because the reactivity with the silicon substrate is slightly lower.

### REFERENCE SIGNS LIST

1 SOLAR BATTERY CELL

2 SILICON SUBSTRATE

3 FRONT-SURFACE ASPERITIES

4 n-TYPE DIFFUSION LAYER

5 ANTI-REFLECTION FILM

6 FRONT-SURFACE ELECTRODE

7 PASSIVATION FILM

8 OPENING

9 ALUMINUM ELECTRODE

10 ALLOY LAYER

11 BSF LAYER

12 Al—Si ELECTRODE

13 BACK-SURFACE REFLECTING FILM

14 STRIPE-SHAPED ELECTRODES

1. A solar battery cell comprising:
a semiconductor substrate; and
a semiconductor layer having a conductive type and formed on a principal surface on a light-receiving surface side of the semiconductor substrate,
wherein a passivation film is formed on a principal surface on a back-surface side of the semiconductor substrate, at least one opening is provided in the passivation film, a first back-surface electrode is provided on the passivation film so as to overlap an entire area occupied by the opening and to cover the opening, and a second back-surface electrode is provided on the passivation film so as to overlap an entire area occupied by the first back-surface electrode and to cover the first back-surface electrode.

2. The solar battery cell according to claim 1, wherein the second back-surface electrode is formed from an alloy containing at least aluminum and silicon.

3. The solar battery cell according to claim 2, wherein the composition ratio between silicon and aluminum contained in the second back-surface electrode is 5 to 20 parts by weight of silicon based on 100 parts by weight of aluminum.

4. The solar battery cell according to claim 1, wherein the opening and the first back-surface electrode each have a stripe shape.

5. A method of manufacturing a solar battery cell, the solar battery cell comprising: a semiconductor substrate; and a semiconductor layer having a conductive type and formed on a principal surface on a light-receiving surface side of the semiconductor substrate, wherein a passivation film is formed on a principal surface on a back-surface side of the semiconductor substrate, at least one opening is provided in the passivation film, a first back-surface electrode is provided on the passivation film so as to overlap an entire area occupied by the opening and to cover the opening, and a second back-surface electrode is provided on the passivation film so as to overlap an entire area occupied by the first back-surface electrode and to cover the first back-surface electrode,
the method comprising:
forming the first back-surface electrode at a position conforming to the opening by printing; and
forming the second back-surface electrode over the formed first back-surface electrode by printing.

6. The solar battery cell according to claim 1, wherein the semiconductor substrate includes front-surface asperities formed on the principal surface on the light-receiving surface side, and the semiconductor layer is formed along the front-surface asperities and includes an anti-reflection film formed on the light-receiving side of the semiconductor layer.
